(19) United States
(12) Patent Application Publication
(10) Pub. No.: US 2024/0166557 A1
(43) Pub. Date: May 23, 2024

(54) ANGULAR PHYSICAL VAPOR DEPOSITION FOR COATING SUBSTRATES

(71) Applicant: 3M INNOVATIVE PROPERTIES COMPANY, St. Paul, MN (US)

(72) Inventors: Joshua M. Fishman, St. Louis Park, MN (US); Paul B. Armstrong, St. Paul, MN (US); Amir Gharachorlou, Woodbury, MN (US); Kathleen M. Humpal, Stillwater, MN (US); Melissa A. Lackey, Woodbury, MN (US); Christopher S. Lyons, St. Paul, MN (US); Mark J. Pellerite, Woodbury, MN (US); James A. Phipps, River Falls, WI (US); Jeffrey L. Solomon, Centerville, MN (US); Karl K. Stensvad, Eagan, MN (US); Tarris A. Sveback, Maplewood, MN (US); Brylee David B. Tiu, Minneapolis, MN (US)

(21) Appl. No.: 18/551,421

(22) PCT Filed: Apr. 4, 2022
(86) PCT No.: PCT/IB2022/053120

§ 371 Date: Sep. 20, 2023

Related U.S. Application Data
(60) Provisional application No. 63/184,972, filed on May 6, 2021.

(51) Int. Cl. C03C 17/38

(52) U.S. Cl. CPC C03C 17/38; C03C 2217/252; C03C 2218/151

(57) ABSTRACT

Described herein is coated article comprising: (a) a substrate comprising a ceramic, a glass, or a glass ceramic, wherein the substrate comprises a surface, the surface comprising a continuous upper portion and a plurality of lower portions, wherein each lower portion is connected to the upper portion by at least one sidewall; and (b) a first layer comprising a material capable of physical vapor deposition, wherein the first layer is disposed on the continuous upper portion and at least a portion of each sidewall and wherein at least a portion of each lower portion is free of the first layer. Methods of making such coated articles are described herein, wherein the substrate is coating via angular physical vapor deposition.

### TECHNICAL FIELD

Angular physical vapor deposition onto a substrate comprising features is discussed to form selective coating of a patterned substrate.

### SUMMARY

Biological assays frequently employ single-use consumables. Often, the consumables are patterned to assist with the assay detection or to enable multiple unknowns to be assayed at once, sometimes called multiplexing. One such consumable is a substrate with nano-sized features, such as wells, which can be used as a flow cell for biochemical and pharmaceutical assays or as a biochemical sensor. Traditionally, these patterned substrates are manufactured using an intricate and expensive wafer-based photolithographic process that includes the use of cleanroom conditions, and multiple chemical-mechanical planarization (CMP), spin coating, imaging and washing steps to etch nano-sized wells into a substrate and functionalize the substrate to carry out the biological assay.

To reduce the financial burden for end users and make the assays more accessible for new markets, it is necessary to reduce the costs of the consumables, including the preparing of the patterned glass or silicon substrates and functionalizing the substrate to ultimately perform the desired biological assay. Additionally, and/or alternatively, there is a desire to identify substrates for nanopatterned arrays that are not as fragile as silicon wafers.

In one aspect, a coated article is described comprising: (a) a substrate comprising a ceramic, a glass, or a glass ceramic, wherein the substrate comprises a surface, the surface comprising a continuous upper portion and a plurality of lower portions, wherein each lower portion is connected to the upper portion by at least one sidewall; and (b) a first layer comprising a material capable of physical vapor deposition, wherein the first layer is disposed on the continuous upper portion and at least a portion of each sidewall and wherein at least a portion of each lower portion is free of the first layer.

In another aspect, a method of making an article is described, the method comprising: (a) obtaining a substrate comprising ceramic, glass, or combinations thereof, wherein the substrate comprises a surface, the surface comprising a continuous upper portion and a plurality of lower portions, wherein each lower portion is connected to the upper portion by at least one sidewall; and (b) depositing a material capable of physical vapor deposition from a source onto the surface of the substrate to form a coated substrate, wherein the substrate is held to an angle versus the source such that the material is disposed on the continuous upper portion and at least a portion of each sidewall and wherein at least a portion of each lower portion is free of the material.

The above summary is not intended to describe each embodiment. The details of one or more embodiments of the invention are also set forth in the description below. Other features, objects, and advantages will be apparent from the description and from the claims.

### BRIEF DESCRIPTION OF DRAWINGS

FIG. 1 is a cross-sectional view of substrate 2 according to one exemplary embodiment of the present disclosure;

FIGS. 2A-2D are cross-sectional views of exemplary cavities in a substrate;

FIG. 3A is a top view of an exemplary coated substrate, while FIG. 3B is a cross-sectional schematic view of coated article 30 according to one embodiment of the present disclosure;

FIG. 4 is a diagram of a sputter coating configuration according to one embodiment of the present disclosure;

FIG. 5A top down view of Example 4 coated substrate and FIG. 5B is cross-sectional view of Example 4 of the present disclosure;

FIG. 6 is cross-sectional view of Example 5 of the present disclosure; and

FIG. 7 is a top down view of Comparative Example B.

### DETAILED DESCRIPTION

As used herein, the term

“a”, “an”, and “the” are used interchangeably and mean one or more;

“and/or” is used to indicate one or both stated cases may occur, for example A and/or B includes, (A and B) and (A or B);

“fluorinated” refers to a molecule comprising at least one carbon-fluorine bond;

“interpolymerized” refers to monomers that are polymerized together to form the polymer backbone (in other words, the main continuous chain of the polymer backbone);

“monomer” is a molecule which can undergo polymerization which then forms part of the essential structure of a polymer;

“polymer” is a molecule comprising numerous repeat interpolymerized monomeric units, often greater than 10. A polymer has a sufficient molecular weight such that the addition of a single monomeric unit does not result in a significant change in physical properties. An exemplary number average molecular weight for a polymer is at least 1000, 5000, 10000, 50000, 100000, 200000, 500000, or even 1000000 grams/mole as determined by techniques known in the art such as gel permeation chromatography;

“oligomer” is a molecule comprising only a few repeat interpolymerized monomeric units, often 2-9 interpolymerized repeat monomeric units. An exemplary number average molecular weight for an oligomer can be less than 5000, 3000, 2000, 1500, 1000, or even 500 grams/mole as determined by techniques known in the art; and

“small molecule” refers to a lower molecular weight compound, not comprising repeating interpolymerized monomeric units. Generally, the small molecule has a number average molecular weight of less than 1000, 800, or even 500 grams/mole as determined by techniques known in the art.

As used herein “glass” refers to amorphous oxide material exhibiting a glass transition temperature; “glass-ceramic” refers to a material formed by heat treatment of a glass to nucleate ceramic crystals in the amorphous matrix, and “ceramic” refers to a crystalline inorganic material that has strong covalent bonds.

Also herein, recitation of ranges by endpoints includes all numbers subsumed within that range (e.g., 1 to 10 includes 1.4, 1.9, 2.33, 5.75, 9.98, etc.).

Also herein, recitation of “at least one” includes all numbers of one and greater (e.g., at least 2, at least 4, at least 6, at least 8, at least 10, at least 25, at least 50, at least 100, etc.).

As used herein, “comprises at least one of” A, B, and C refers to element A by itself, element B by itself, element C by itself, A and B, A and C, B and C, and a combination of all three.

The present description provides a method of selectively coating a substrate comprising a plurality of cavities using physical vapor deposition.

### Substrates

The substrates of the present disclosure are inorganic, specifically ceramic, glass, or glass ceramic.

Glass refers to amorphous materials composed primarily of SiO₂, P₂O₅, B₂O₃, Al₂O₃, GeO₂, alkali or alkaline earth modifiers (e.g., Na₂O, K₂O, Li₂O, CaO, MgO), and combinations thereof. In one embodiment, the glass may include other components such as TiO₂, TeO₂, rare earth oxides, ZnO, etc. Exemplary glass includes amorphous SiO₂, fused quartz, fused silica, soda lime silicate glass, borosilicate, S-glass, E-glass, titanate- and aluminate-based glasses.

Glass ceramics refer to polycrystalline materials that are formed through the controlled crystallization of an amorphous material. The crystallization process is typically a secondary heat treatment of the glass under controlled heating and cooling conditions. Exemplary glass-ceramics are lithium silicates, alkaline earth aluminosilicates, alkaline earth aluminates and rare earth aluminates.

Ceramics refer to polycrystalline materials that have an ordered structure. Ceramics include for example, silicon oxide, aluminum oxide, tin oxide, zinc oxide, bismuth oxide, titanium oxide, zirconium oxide, lanthanide oxides, mixtures thereof and the like and other metal salts such as calcium carbonate, calcium aluminate, magnesium aluminosilicate, potassium titanate, cerium ortho-phosphate, hydrated aluminum silicate, mixtures thereof, and the like.

In one embodiment, the substrate comprises silicon dioxide, zirconium dioxide, or combinations thereof.

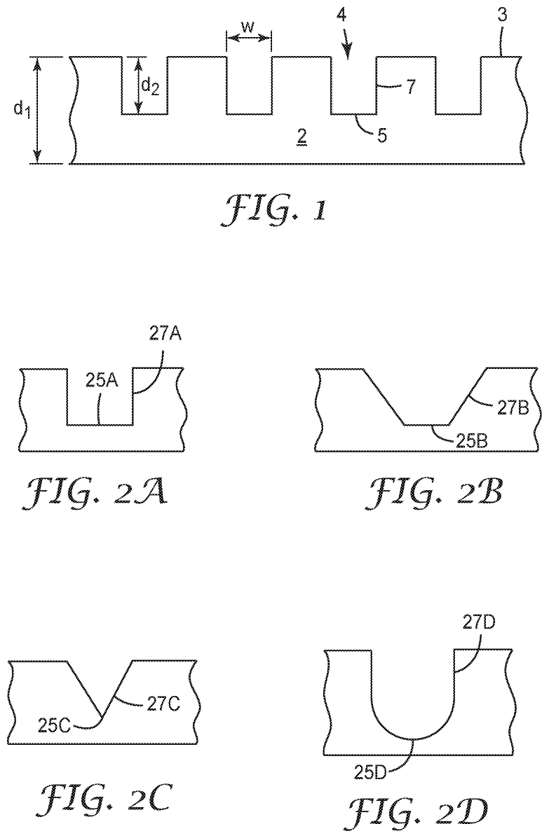

The substrates of the present disclosure are patterned, having a plurality of cavities (or depressions) along a major surface of the substrate, wherein the top of each cavity intersects the top surface of the substrate. See for example FIG. 1, where a cross-section of substrate 2 comprises continuous upper portion 3 and side wall 7 connecting the upper portion of the substrate surface to lower portion 5 of the substrate surface. The side walls and lower portion form cavity 4. Depending on the final use of the article, in some embodiments, the cavities are spaced sufficiently apart such that each of the cavities is spatially separated to enable optical detection of the individual cavities. The separation between the cavities can depend on the detection scheme used. In one embodiment, the center to center spacing (or pitch) between adjacent cavities along the upper portion of the substrate's surface is at least 30, 50, 100, 150, 200, 350, 500, or even 1000 nm (nanometers) apart. In one embodiment, the center to center spacing between adjacent cavities along the upper portion of the substrate's surface is at most 75, 100, 200, 300, 500, 1000, 5000, or even 10000 nm apart. Typically, the cavities are positioned along the substrate surface in a pattern having a repeat unit. The repeat unit can be triangular, quadrilateral (e.g., square, rhombus, rectangle, parallelogram), hexagonal, or other repeat pattern shape, which may be symmetric or asymmetric in nature.

In one embodiment, the substrate comprises cavities having a continuous sidewall, such as the case with a cylinder, truncated spheroid, or cone shaped cavity. In another embodiment, the substrate comprises cavities having more than one side wall, such as with a prism or pyramid shaped cavity.

In one embodiment, the at least one side wall, which forms the cavity is substantially perpendicular to the continuous upper portion of the substrate. Thus, the cavity has a distinct side wall and lower portion.

In another embodiment, the at least one side wall is oblique to the continuous upper portion of the substrate's surface. In one embodiment, the side wall has a taper angle of greater than 0° and less than 25°, or even greater than 2° and less than 10° when measured with respect to a plane along the continuous upper surface of the substrate. In the instance of oblique side wall constructions, the cavity may have a distinct side wall and lower portion (for example, a truncated cone-shaped cavity); in other instances, the tapered side wall(s) may converge to a point (e.g., a cone-shaped cavity), wherein the lower portion of the substrate surface would be the very bottom of the cavity.

In FIG. 1, d₁ corresponds to the thickness of the substrate, as measured from continuous upper surface 3 to the opposing surface of the substrate. In FIG. 1, d₂ corresponds to the depth of the cavity, as measured from continuous upper surface 3 to the lowest portion of the cavity. In FIG. 1, w corresponds to the width of the cavity as it intersects the top surface of the substrate.

The plurality of cavities may have any shape as known in the art. For example, the cavities may be in the shape of a cylinder; prism (e.g., rectangular prism, pentagonal prism, hexagonal prism, octagonal prism, etc.) or frustum thereof; cone; conical frustum; pyramid (e.g., triangular pyramid, square pyramid, hexagonal pyramid, etc.) or frustum thereof; hemisphere; truncated spheroid (e.g., oblate or prolate spheroid); or combinations thereof. Exemplary cross-sections of cavities are shown in FIGS. 2A-2D, where 2A has flat bottom 25A and straight sidewall 27A; FIG. 2B has flat bottom 25B and sloped sidewall 27B; FIG. 2C has bottom apex 25C and sloped sidewall 27C; and FIG. 2D has a rounded shape with sidewall 27D curving to bottom 25D.

The opening to the cavity along the top surface of the substrate may have any shape as known in the art. Exemplary opening shapes include: round (e.g., circle or oval), polygonal (e.g., triangle, square, rectangle, pentagon, etc.), and combinations thereof.

Typically, the largest portion of the cavity diameter (typically the opening to the cavity) intersects the upper portion of the substrate's surface. Generally, the largest portion of the cavity has an average diameter of at least 25, 30, 40, 50, 75, 100, or even 200 nm (nanometer). In one embodiment, the largest portion of the cavity has an average diameter of at most 200, 300, 400, 500, 600, 800, 1000, 1200, 1500, 2000, 4000, 5000, 6000, 8000, or even 10000 nm.

In one embodiment, a cavity defined by the at least one sidewall and the lower portion has a volume of at least 1,000,000; 2,000,000; 4,000,000; 6,000,000; 10,000,000; 20,000,000; or even 50,000,000 nm³. In another embodiment, a cavity defined by the at least one sidewall and the lower portion has a volume of at most 30,000,000; 50,000,000; 70,000,000; 90,000,000; 100,000,000; 500,000,000; 1,000,000,000; 2,000,000,000; or even 5,000,000,000 nm³.

In one embodiment, the cavity has an average depth, d₂, as measured from the upper portion of substrate's surface of at least 25, 50, 75, 100, 200, 250, 300, 400, or even 500 nm. In one embodiment, the cavity has an average depth, d₂, as measured from the upper portion of substrate's surface of at most 200, 500, 1000, 2000, 5000, 10000, 15000, or even 20000 nm.

In one embodiment, the substrate has an average thickness, d₁, of at least 25, 50, 75, 100, or even 200 micrometers and at most 400, 500, 600, 800, 1000, 2000, 5000, 8000, or even 10000 micrometers.

The patterned inorganic substrate comprising a plurality of cavities may be formed using techniques known in the art, including, photolithography, milling, gel casting, slip casting, sol-gel casting, injection molding, and etching.

In one preferred embodiment, a patterned ceramic substrate is made using a casting technique, wherein a casting material is placed within a mold. The method should have good replication between the mold and the casting material, even with small and/or complex features. In one embodiment, the casting material is a sol comprising (a) 2 to 65 weight percent surface modified silica particles, (b) 0 to 40 weight percent polymerizable material that does not contain a silyl group, (c) 0.01 to 5 weight percent radical initiator, and (d) 30 to 90 weight percent organic solvent medium, wherein each weight percent is based on the total weight of the sol as described in U.S. Pat. Publ. No. 2019-0185328 (Humpal et al.), herein incorporated by reference. In another embodiment, the casting material comprises (a) 20 to 60 weight percent zirconia-based particles based on a total weight of the reaction mixture, the zirconia-based particles having an average particle size no greater than 100 nanometers and containing at least 70 mole percent ZrO₂, (b) 30 to 75 weight percent of a solvent medium based on the total weight of the reaction mixture, the solvent medium containing at least 60 percent of an organic solvent having a boiling point equal to at least 150° C., (c) 2 to 30 weight percent polymerizable material based on a total weight of the reaction mixture, the polymerizable material including a first surface modification agent having a free radical polymerizable group; and (d) a photoinitiator for a free radical polymerization reaction as described in U.S. Pat. Publ. No. 2018-0044245 (Humpal et al.), herein incorporated by reference.

In one embodiment, the patterned substrates of the present disclosure are net shape manufactured, meaning that the method used to make the substrate, generates a substrate in its final shape or as near as possible to its final shape, without further processing. The patterned wafer-based substrates used in photolithographic techniques are not net shape manufactured. For example, the cavities are formed in the wafer and then the wafer is further processed (e.g., polishing, lithographic techniques, etc.) before it is subsequently cut to produce parts with a defined shape and size. Advantageously, the two Humpal et al. patent publications disclosed above can produce net shape manufactured monolithic parts.

In one embodiment, the upper and/or lower portion of the substrate surface has a roughness. For example, because the two Humpal et al. patent publications disclosed above produce net shape manufactured parts with no subsequent planarization to an atomic level, they can generate patterned substrates with a surface roughness. Such surface roughness can be observed in FIG. 7. The amount of surface roughness can vary depending on the particles used in the casting material. In one embodiment, the upper and/or lower portion of the substrate surface has an average surface roughness of at least 1, 5, 10, 15, 20, 25, 40, 50, 60, or even 75 nm. In one embodiment, the upper and/or lower portion of the substrate surface has an average surface roughness of at most 50, 60, 70, 80, 90, 100, or even 125 nm. In general, the surface roughness should not exceed 50, 60, or even 70% of the cavity depth, d₂, to maintain fidelity of the features (i.e., cavities). A roughened surface can lead to a higher overall surface area than if the surface was planarized to an atomic level. A higher surface area can be desirable as more biological targets can be bound per 2-dimensional unit area, leading to a higher signal in the same 2-dimensional projected area.

In the present disclosure, the patterned substrates are coated using physical vapor deposition techniques to selectively coat a first layer onto the patterned substrate.

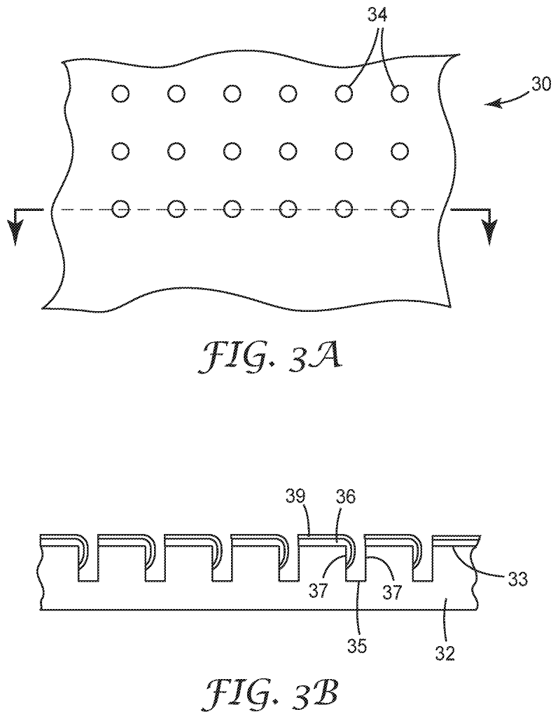

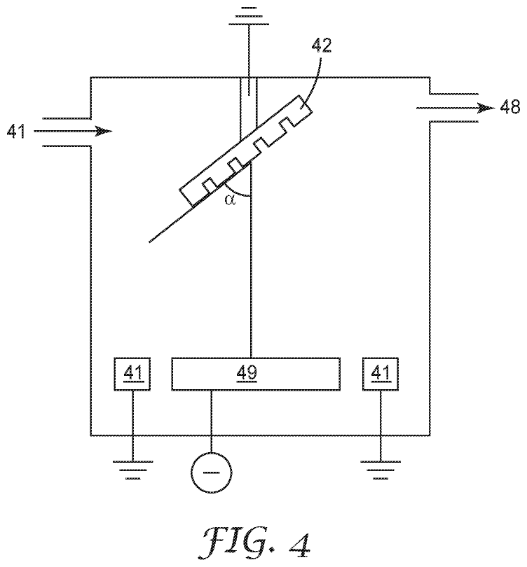

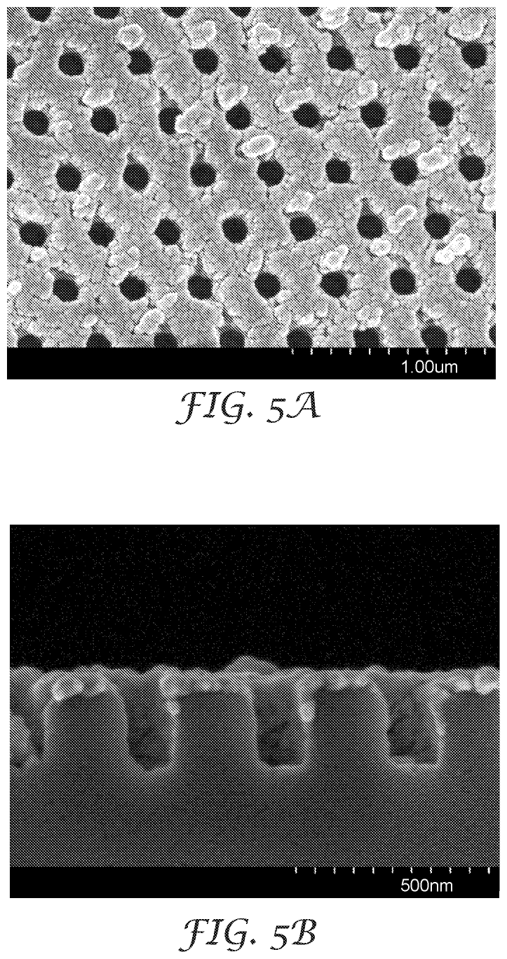

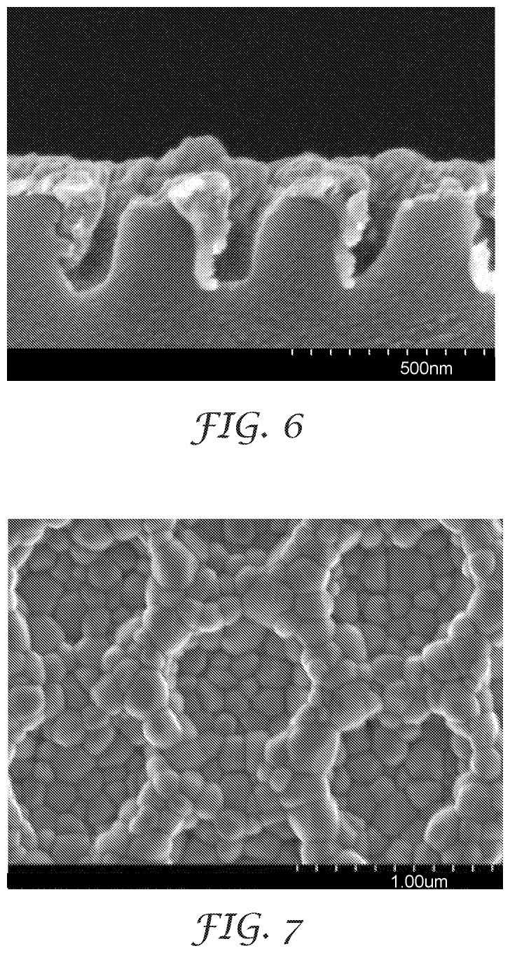

Shown in FIG. 3A is a top-down view of coated article 30. Coated article 30 comprises a plurality of cavities 34. As shown in FIG. 3A, the cavities are arranged in a square unit cell pattern. FIG. 3B is a cross-section of the coated article shown in FIG. 3A taken at the indicated line. Substrate 32 comprises a continuous upper portion 33 and a plurality of lower portions. Each lower portion 35 of the substrate surface is connected to the upper portion of the surface by at least one sidewall 37. As shown in FIG. 3B, first layer 36 is disposed on continuous upper portion 33 of the substrate surface and on at least a portion of sidewall 37. At least a portion of the lower portion of the surface 35 is not contacted by first layer 36. Optional second layer 39 is disposed on top of first layer 36.

The first layer is a material capable of physical vapor deposition. The material capable of physical vapor deposition maybe a polymer, oligomer, or small molecule. In one embodiment, the material capable of physical vapor deposition comprises a non-fluorinated polymer, a fluorinated polymer, a non-fluorinated oligomer, a fluorinated oligomer, a non-fluorinated small molecule, a fluorinated small molecule, or blends thereof. The small molecule may be crystalline or amorphous in nature. In one embodiment, the fluorinated polymer comprises interpolymerized monomeric units of tetrafluoroethylene, vinylidene fluoride, hexafluoropropylene, 2,2-bistrifluoromethyl-4,5-difluoro-1,3-dioxole, or combinations thereof. Exemplary organic materials capable of physical vapor deposition to form the first layer include: polytetrafluoroethylene, polyhexafluoropropylene, polyvinylidene fluoride, poly(2,2-bistrifluoromethyl-4,5-difluoro-1,3-dioxole), and blends thereof.

In one embodiment, the material capable of physical vapor deposition comprises an inorganic metal-containing material. The metal in the metal-containing material can be any metal known; notable metals include Al, Au, Ag, Co, Cr, Cu, Ge, Ga, In, Nb, Ni, Si, Sn, Ti, V, Zr, and Zn. Inorganic metal-containing materials include: a neat metal, a metal alloy, a metal oxide, a metal nitride, a metal oxynitride, a metal fluoride, a metal sulfide, a metal carbide, and mixtures thereof. Exemplary inorganic metal-containing materials that can be used to form the first layer include: Al, Ti, Au, Ag, Cu, Ni, V, Co, Cr, AuAg, silicon oxides (such as SiO₂, SiCₓO_{y} or SiAlₓO_{y} where x can be any value (integer and/or fraction) greater than zero and y can be any value greater than zero so long as the oxidation state of the atoms are not over fulfilled), titanium oxides, aluminum oxides, and mixtures and combinations thereof. Depending on the metal, in some embodiments, the metal can oxidize following deposition, for example upon the exposure to air.

The first layer can be visualized using techniques known in the art such as scanning or transmission electron microscopy (SEM or TEM). The thickness of the first layer can be uniform or variable across the substrate. For instance, the thickness often tapers in caliper down the side wall. The first layer typically conformally coats the upper portion of the substrate. In one embodiment, the first layer on the upper portion of the substrate has an average thickness of at most 500, 300, 200, 100, 50, or even 20 nm. In one embodiment, the first layer on the upper portion of the substrate has an average thickness of at least 1, 2, 3, 4, 5, or even 8 nm. The first layer can have an exposed surface roughness that mirrors the underlying surface roughness of the substrate as described above. In some embodiments, the first layer may comprise protrusions, which occur during deposition. The protrusions often are angled relative to upper continuous surface 33 at the same angle as the vapor deposition angle.

Physical vapor deposition refers to the physical transfer of the material (e.g., a metal or polymer) from a material-containing source or target to the substrate. Physical vapor deposition may be viewed as involving atom-by-atom deposition although in actual practice, the material may be transferred as extremely fine bodies constituting more than one atom per body. Once at the surface, the deposited material may interact with the surface physically, chemically, ionically, and/or otherwise. In physical vapor deposition, a layer of source material is formed by condensation of atoms or molecules from a gas or vapor onto a surface. Physical vapor deposition is a line-of-sight technique, wherein the source material is deposited directly on surfaces that are in a direct line of sight with the source. Surfaces that are not in a direct line of sight of the source tend to not be directly coated with the source material. Types of physical vapor deposition include, evaporation deposition such as ion plating or arc deposition, thermal evaporation or e-beam evaporation, and sputtering such as magnetron sputtering. Such techniques are known in the art.

In evaporation deposition, the target material can be evaporated by direct or indirect heating using electrical current or an electron beam. The target material must have a sufficiently high vapor pressure to be used in evaporation coating. Typically, this technique is used with pure elements as opposed to compounds. Typically, the evaporation deposition is done at temperatures and under vacuum conditions in which the target material is mobile. For example, temperatures can range between 100 to 1500° C., and pressure can range between 10⁻⁴ Pa to 10⁻² Pa, depending on the target material.

In sputter deposition, a vapor phase of the target material is formed by applying a voltage to the target material in the presence of a noble gas (e.g., argon). A plasma forms between the target material and the substrate. Argon ions generated in the plasma collide with the target material at high energy and release free surface atoms. These (neutral) atoms then deposit as a thin layer on the substrate. When a reactive gas is used during the process it is called reactive sputtering and when a magnetic field is used during the process, it is called magnetron sputtering. The magnetic field techniques can be used to increase the deposition rate. Sputter coating generally results in lower deposition rates than evaporation coating, but is advantageous for use with materials that are challenging to evaporate. However, in sputtering, the noble gas (e.g., argon) atoms are typically present in the deposited layer. Typically, sputtering is done at higher pressures than the evaporation technique and uses more complicated instrumentation.

Because physical vapor deposition is a line-of-sight technique, it has been discovered that when the patterned substrate is positioned at an angle from the source material, the deposition angle enables selective coating of the patterned substrate.

Shown in FIG. 4 is a schematic of one embodiment for sputter coating a patterned substrate. Patterned substrate 42 is positioned at an angle such that the upper portion of the substrate's surface is at a deposition angle, α, which is relative to the perpendicular of the sputtering target 49 surface. Patterned substrate 42 and sputtering target 49 are positioned in a vacuum chamber. Argon gas enters the chamber through inlet 41 and exits through outlet 48. A potential is placed between sputtering target 49 cathode and grounded anode 41. The argon gas generates a plasma gas, generating positive argon atoms Ar⁺ which energetically strike the sputtering target, sending target material linearly from the surface.

During physical vapor deposition, the patterned substrate and the source material should be held at an angle α determined by the aspect ratio of the cavities, d₂/w, where d₂ is the depth of the cavity and w is the width of the cavity. In one embodiment, the aspect ratio can range from 0.5:1 to 50:1, preferably from 0.5:1 to 20:1, and more preferably from 1:1 to about 10:1. In one embodiment, the deposition angle, α, is at least 2, 5, or 10°; and at most 15, 20, 25, 30, 40, 50, or even 60°. The deposition angle, α, and aspect ratio of the cavity can be adjusted to ensure the absence of material from vapor depositing onto a portion of the cavity. The preferred range of values of the deposition angle α is:

α≤arctan(d₂/w)

to create the selective patterning of only a portion of the cavities. In one embodiment, when d₂=w the aspect ratio d₂/w=1, arctan(d₂/w)=45°, and the preferred deposition angle α is less than or equal to 45°, 40°, 30°, 20°, 10°, or even 5°. In one embodiment, when the aspect ratio d₂/w=1.5, arctan(d₂/w)=56° and the preferred deposition angle α is less than or equal to 56°, 45°, 35°, 25°, 15°, or even 5°. In one embodiment, when the aspect ratio d₂/w=1.5 the preferred deposition angle is less than or equal to 56°, 45°, 35°, 25°, 15°, or even 5°. In some instances, it may be desirable to place a mask or shield between the sputtering target and patterned substrate (not shown in FIG. 4) to further collimate the flux of ejected target material toward the patterned substrate. If desired, after the physical vapor coating of one side of the cavities, the coated substrate can be repositioned, while still remaining at an angle relative to the target, to selectively coat another portion of the side wall. This can be repeated as many times as desired. It should be noted that each time the substrate is subjected to deposition, the thickness of the first layer which is deposited along the continuous upper portion of the substrate gets larger. The repeated vapor deposition step can also lead to thickness differences of the first layer between the amount of first layer located on the continuous upper portion of the substrate surface and the side wall(s) in the coated part.

As mentioned above, physical vapor deposition is considered a line of sight deposition process. Although not wanting to be limited by theory, it is believed that the edge of the cavity along the upper portion of the substrate surface shadows at least a portion of a sidewall, preventing the deposition of the target material thereon. This allows for the selective coating of the patterned substrate along the upper surface of the substrate and on at least a portion of at least one sidewall.

The process as discussed above, enables portions of the cavities to remain uncoated as shown in FIG. 3B. In one embodiment, at least 15, 20, 25, 40, 50, 60, 75, or even 80% of the surface of the cavity is not coated with the first layer.

Thus, the present disclosure teaches a lower cost approach to selectively coat an inorganic substrate comprising a plurality of cavities. The selective coating can then be exploited to construct articles having different functionalization between the cavities and the continuous upper surface.

In one embodiment, the patterned substrate selectively coated with the material capable of physical vapor deposition, can be coated with a second coating layer, which can bind to the first layer. Thus, this second coating layer would be disposed on top of the first layer, leaving the portions of the substrate not covered by the first layer also not covered by the second layer. In other words, at least a portion of each lower portion of the substrate is free of both the first and the second layer.

In one embodiment, the second layer comprises a compound (e.g., small molecule, oligomer, or polymer) having at least one functional group that can bind (e.g., bonding such as covalent, electrostatic, dative, ionic, hydrogen, hydrophobic, van der Waals, etc.) to the first layer, but will not substantially bind (less than 1%, preferably none) to the substrate. Such functional groups include: silane, thiol, phosphate, phosphonic acid, monophosphate ester, sulfate, sulfonic acid, carboxylic acid, hydroxamic acid, amines, amine-containing heteroaromatic ring, nitrogen-containing heteroaromatic ring, and combinations thereof. The compound of the second layer can comprise one or more functional groups (e.g., at least two functional groups, or even at least four functional groups). If there is a plurality of functional groups on a compound, the functional groups may be the same or different.

The building of layers onto the patterned substrate selectively coated with the material capable of physical vapor deposition, such as the second layer and subsequent layers, can enable the construction of various assays or sensors for biological and chemical analysis based on the tuning of the layers. For example, if the coated article is used in a high-throughput assay such as nucleic acid and peptide sequencing, or protein, gene and other biochemical and pharmaceutical assays, the second coating layer would be biologically inert. By having the second coating layer biologically inert and the interior of the cavities functionalized to bind target analytes, a biological solution can be passed over the coated article and interact primarily and/or exclusively with the cavities. If the coated article is used in a biosensor application, such as a using the patterned substrate with surface plasmon resonance, the second coating layer would be biologically active. The biologically active layer could be functionalized to enable biochemical sensing of a desired target.

As mentioned above, the second coating layer can be biologically active or inactive depending on the final application and the compound used to generate the second coating layer can be biologically active or inert. If the compound is biologically active, the compound can be used to selectively bind (e.g., bonding such as covalent, electrostatic, ionic, hydrogen, hydrophobic, van der Waals, etc.) biological molecules. The functional groups mentioned above (i.e., silane, thiol, phosphate, phosphonic acid, monophosphate ester, sulfate, sulfonic acid, carboxylic acid, hydroxamic acid, amine-containing heteroaromatic ring, and nitrogen-containing heteroaromatic ring) can be found naturally on many biological molecules, e.g. proteins or nucleic acids, on synthetic compounds, or on derivatives of naturally occurring biological molecules. Examples of biologically active materials that can be used as the second material include antibodies, nucleic acids, lectins, drug-conjugates, carbohydrates, proteins, lipids, secondary metabolites, etc. If the compound is biologically inert, the compound can be used to resist the non-specific association of biological molecules. Examples of biologically inert materials that can be used as the second material include fluorinated molecules or polymers, polyalkylene oxides such as polyethylene glycol, polyolefins such as polyethylene or polyethylene copolymers, a silicone, and fluoroether containing thiols and phosphates. Examples of fluorinated molecules or polymers include fluoroether containing phosphates of the formula: R_{f}—[X¹—R²—X²—R³(P(O)(OH)₂)ₙ]ₘ
wherein
R_{f} is a perfluoroether group,
R² is a hydrocarbyl group including alkylene, arylene, alkarylene and aralkylene;
R³ is a hydrocarbyl group including alkylene, arylene, alkarylene and aralkylene;
X¹ is —CH₂—O—, —O—, —S—, —CO₂—, —CONR¹—, or —SO₂NR¹⁻ where R¹ is H or C₁-C₄ alkyl;
X² is a covalent bond, —S—, —O— or —NR¹—, —CO₂—, —CONR¹—, or —SO₂NR¹⁻ where R¹ is H or C₁-C₄ alkyl;
n at least one;
m is 1 or 2 as disclosed in U.S. Pat. No. 10,757,108 (Armstrong et al.) herein incorporated by reference for its teaching of such fluorinated materials. Examples of fluorinated molecules or polymers include fluoroether containing thiols of the formula: Rf [C(═O)—N(R)-Q-(SH)x]y wherein Rf is a monovalent or divalent perfluoropolyether group; R is hydrogen or alkyl; Q is a divalent, trivalent, or tetravalent organic linking group; x is an integer of 1 to 3; and y is an integer of 1 or 2. Such fluorinated thiols are disclosed in U.S. Pat. Publ. No. 2011/0237765 (Iyer et al.) herein incorporated by reference for its teaching of such fluorinated materials. Examples of functionalized oligoethylene or polyethylenes are poly(vinyl phosphonate), (12-phosphonododecyl)phosphonic acid, poly((meth)acrylic acid), copolymers of (meth)acrylic acid), poly(vinylsulfonic acid), poly(vinyl sulfate), poly(4-styrenesulfonic acid) all sold by Sigma-Aldrich (St. Louis, MO). Examples of functionalized polyalkylene oxides are SIH6188.0 ([hydroxy (polyethyleneoxy)propyl]-triethoxysilane, SIM6491.7 (11-(2-methoxyethoxy)undecyltrimethoxysilane), SIM6492.56 (O-(methoxypoly(ethyleneoxy))-N-triethoxysilyl-propyl)carbamate), SIM6492.58 (2-(methoxypoly(ethyleneoxy)6-9propyl) dimethylmethoxysilane), SIM6482.7 (2-(methoxypoly(ethyleneoxy)6-9propyl) trimethoxysilane), SIM6482.72 (2-(methoxypoly(ethyleneoxy)9-12propyl) trimethoxysilane), SIM6482.73 (2-(methoxypoly(ethyleneoxy)21-24propyl) trimethoxysilane), SIM6493.3 (methoxytri(ethyleneoxy)propyl)hexamethyl-trisilanoxyethyltriethoxysilane), SIM6493.4 (methoxytri(ethyleneoxy)propyl) trimethoxysilane), SIM6493.7 (methoxytri(ethyleneoxy)undecyltrimethoxysilane), SIM6493.9 (methoxytri(ethyleneoxy)(11-trimethoxysilyl)undecanoate), SIT8186.3 (triethyoxysilylpropoxy (polethyleneoxy)decanoate), SIB1543.0 (bis(methoxy(triethyleneoxy)propyl)dimethoxysilane), SIB1824.81 (N,N′-bis-((3-triethoxysilylpropyl)aminocarbonyl)polyethylene oxide, 7-10 EO), SIB1824.82 (N,N′-bis-((3-triethoxysilylpropyl)aminocarbonyl)polyethylene oxide, 10-15 EO), SIB1824.84 (bis-((3-triethoxysilylpropyl)polyethylene oxide, 25-30 EO), SIT8171.2 (tridecafluoro-1,1,2,2-tetrahydrooctyl)-(methoxypoly(ethyleneoxy)propyldimethoxysilane), SIA0078.0 (2-((acetoxy(polyethyleneoxy)propyl)triethoxysilane) from Gelest or poly(ethyleneglycol)methyl ether thiol, O-[2-(3-Mercaptopropionylamino)ethyl]-O′-methylpolyethylene glycol, O-(2-Carboxyethyl)-O′-methyl-undecaethylene glycol, 2-[2-(2-Methoxyethoxy)ethoxy]acetic, Methoxypolyethylene glycol 5000 acetic acid, Methoxypolyethylene glycol 5,000 propionic acid or O-Methyl-O′-succinylpolyethylene glycol from Sigma-Aldrich. Examples of functionalized silicones are mercaptosilicones SMS-022, SMS-042 and SMS-992 from Gelest (Morrisville, PA) or aminosilicones and carboxymodified silicones from Shin-Etsu.

### EXAMPLES

Unless otherwise noted, all parts, percentages, ratios, etc. in the Examples and the rest of the specification are by weight. Unless otherwise indicated, all other reagents were obtained, or are available from fine chemical vendors such as Sigma-Aldrich Company (St. Louis, MO) or VWR International (Radnor, PA), or may be synthesized by known methods. Table 1 (below) lists materials used in the examples and their sources.

TABLE 1
Materials List

| DESIGNATION | DESCRIPTION AND SOURCE |
|---|---|
| NALCO 2326 | Colloidal silica nanoparticles, nominally 16 weight percent, 5 nm |
| | particle size, obtained under trade designation “NALCO 2326” from |
| | Nalco Company (Naperville, IL, USA). |
| Sol S1 | A concentrated sol of surface-modified silica nanoparticles prepared as |
| | described in Example 1 of U.S. Pat. Publ. No. 20190185328 (Humpal |
| | et al.). |
| 3-(trimethoxysilyl)propyl | 3-(trimethoxysilyl)propyl methacrylate obtained from Alfa Aesar |
| methacrylate | (Ward Hill, MA, USA). |
| Sol Z1a | A zirconia-based sol prepared and processed in the manner described |
| | for Sol-S2 (Example 2) of U.S. Patent Application Publication |
| | US20180044245 (Humpal et al.). |
| Diethylene glycol | Obtained from Alfa Aesar. |
| monoethyl ether | |
| MEEAA | 2-[2-(2-Methoxyethoxy)ethoxy]acetic acid obtained from Sigma- |
| | Aldrich (St. Louis, MO, USA). |
| HEA | 2-Hydroxyethyl acrylate obtained from Alfa Aesar. |
| Octyl acrylate | Prepared as described in Example 4 of U.S. Pat. No. 9,908,837 |
| | (Colby et al.). |
| Acrylic acid | Acrylic acid obtained from Alfa Aesar. |
| SR351 H | Trimethylolpropane triacrylate obtained from Sartomer USA (Exton, |
| | PA, USA) under the trade designation “SR351 H”. |
| CN975 | Hexafunctional urethane acrylate obtained from Sartomer USA |
| | (Exton, PA, USA) under the trade designation “CN975”. |
| OMNIRAD 819 | UV/Visible photoinitiator obtained from IGM Resins (Waalwijk, The |
| | Netherlands) under the trade designation “OMNIRAD 819”. |
| DPICl | Diphenyliodonium chloride obtained from Alfa Aesar. |
| CPQ | Camphorquinone obtained from Alfa Aesar. |
| EDMAB | Ethyl 4-(dimethylamino)benzoate obtained from Sigma-Aldrich. |
| Al wire | 1100 grade 0.062 in diameter aluminum wire available from Phifer |
| | Wire Products (Tuscaloosa, Al) |
| PTFE target | Polytetrafluoroethylene sputter target, 3 inch diameter by 0.125 inch |
| | cylinder, copper backing plate 0.125 inch, indium bonded available |
| | from QS Advanced Materials (New York, NY) |
| Au target | Gold sputter target, 3 inch diameter by 0.125 inch cylinder available |
| | from Target Materials, Inc. (Columbus, OH) |
| AgAu target | 50:50 silver:gold alloy sputter target, 3 inch diameter by 0.125 inch |
| | cylinder available from DHF Technical Products (Los Angeles, CA) |
| Al target | Aluminum sputter target, 3 inch diameter by 0.250 inch cylinder |
| | available from Kurt J. Lesker Co. (Clairton, PA) |
| Norbornene silane | [(5-bicyclo[2.2.1]hept-2-enyl)ethyl]trimethoxysilane, obtained under |
| | catalogue number SIB0988.0 available from Gelest, Inc. (Morrisville, |
| | PA) |
| IPA | Isopropyl alcohol available from VWR International |
| ethanol | 200 proof absolute ethanol was manufactured by Koptec available |
| | from VWR International |
| HFPO Thiol | C₃F₇(OCF(CF₃)CF₂)ₙOCF(CF₃)CH₂O(CH₂)₃SH which can be made as |
| | described in Example 5 of U.S. Pat. No. 10,757,108 (Armstrong et al.) |
| HFPO Phosphate Ester | C₃F₇O(CF(CF₃)CF₂O)ₙ CF(CF₃)CH₂OPO(OH)₂, which can be made |
| | following “Preparation of Hexafluoropropylene Oxide-Phosphate |
| | Ester Mn 7000 Daltons” taken from US Pat. Publ. No. 2018/0030285 |
| | (Olson et al.) |
| Novec 7100 | Hydrofluoroether available under the trade designation “3M NOVEC |
| | 7100 ENGINEERED FLUID” (3M Company, Maplewood Mn) |

### Preparative Example 1 (Silica Casting Sol)

Different batches of silica casting sol were used in the examples below. Described hereafter is a representative process to make the silica casting sol. A concentrated sol of surface-modified silica nanoparticles (Nalco 2326 modified with 3-(trimethoxysilyl)propyl methacrylate) in diethylene glycol monoethyl ether, Sol S1, was prepared as described in Example 1 of U.S. Pat. Publ. No. 20190185328. The resulting concentrated silica sol contained 45.66 weight % oxide.

To prepare silica casting sol, a portion of the concentrated sol (881.28 grams) was charged to a 2-liter bottle and combined with diethylene glycol monoethyl ether (2.14 gram), HEA (12.46 grams), octyl acrylate (25.03 grams), SR351 H (220.47 grams), and CN975 (110.02 grams). OMNIRAD 819 (30.18 grams) was dissolved in diethylene glycol monoethyl ether (770.89 grams) and added to the bottle. The sol was passed through a 1-micron filter. The sol contained 19.61 weight % oxide and 57.11 weight % solvent.

### Preparative Example 2 (Zirconia Casting Sol)

Zirconia sol Z1a had a composition of ZrO₂ (97.7 mole %)/Y₂O₃ (2.3 mole %) in terms of inorganic oxides and was prepared and processed as described for Sol-S2 in the Examples Section of U.S. Pat. Publ. No. 20180044245A1.

Diethylene glycol monoethyl ether-based zirconia sol Z1b was produced by adding MEEAA (3.56 weight % with respect to the grams of oxide in the sol) and the appropriate amount of diethylene glycol monoethyl ether (adjusted to the intended final oxide concentration in the sol, e.g., 60 weight %) to a portion of Sol Z1a, and concentrating the sol via rotary evaporation. The resulting sol was 61.50 weight % oxide and 8.11 weight % acetic acid.

To prepare the zirconia casting sol, a portion of sol Z1b (200.89 grams) was combined with diethylene glycol monoethyl ether (29.39 grams), acrylic acid (13.35 grams), HEA (2.53 grams), octyl acrylate (1.26 grams), SR351 H (22.32 grams), and CN975 (11.14 grams). DPICl (0.38 gram) was charged to the bottle and dissolved in the sol. CPQ (0.40 grams) and EDMAB (1.98 grams) were dissolved in diethylene glycol monoethyl ether (27.44 grams) and added to the bottle. The resulting zirconia casting sol was passed through a 1-micron filter.

### Method of Making Substrate

### 1. Shaped Gel Preparation

The casting sol was charged to a mold cavity. The mold cavity was formed by clamping together a metal mold (inner diameter of 25 millimeters (mm)×thickness of 2.26 mm; treated with a release coating and equipped with a filling trough) and a film tool adhered to a 3.3 mm thick acrylic plate. The structured side of the film tool formed part of the mold cavity. The sol was charged to the mold cavity using a 22-gauge blunt tipped needle attached to a 10 milliliters (ml) luer-lok syringe. Once the cavity was filled, the sol was cured (polymerized) for 30 seconds using a LED array positioned 40 mm away from the top of the mold construction. The diodes on the array were spaced 8 mm apart in a 10×10 grid, and they had a wavelength of 450 nm. This process was repeated to make a set of shaped gel articles. The resulting shaped gels replicated the mold features, felt dry, and were robust to handling when removed from the mold.

### 2. Formation of Sintered Articles

2a. Shaped Silica Articles, CC1

The shaped silica gels were dried using supercritical CO₂ extraction in a manner similar to “Method for Supercritical Extraction of Gels” described in U.S. Pat. Publ. No. 20190185328. The shaped silica aerogels were crack-free after drying.

These shaped silica aerogels were then placed on 3 mm diameter quartz rods on 1 mm thick alumina plate and heated in air to remove organic components and densify according to the following schedule.
a) Heat from 25° C. to 200° C. at 180° C./hour rate;
b) Heat from 200° C. to 350° C. at 12° C./hour rate;
c) Heat from 350° C. to 450° C. at 180° C./hour rate;
d) Hold at 450° C. for 2 hours;
e) Heat from 450° C. to 800° C. at 60° C./hour rate;
f) Hold at 800° C. for 2 hours;
g) Heat from 800° C. to 950° C. at 60° C./hour rate;
h) Hold at 950° C. for 4 hours;
i) Heat from 950° C. to 1000° C. at 6° C./hour rate;
j) Hold at 1000° C. for 4 hours;
k) Heat from 1000° C. to 1011° C. at 6° C./hour rate;
l) Hold at 1011° C. for 8 hours;
m) Heat from 1011° C. to 1091° C. at 60° C./hour rate;
n) Hold at 1091° C. for 2 hours; and
o) Cool from 1091° C. to 25° C. at 120° C./hour rate.

The resulting sintered amorphous silica articles (CC1) were crack-free, transparent, and replicated the mold features precisely but reduced in size proportional to an amount of isotropic shrinkage that is determined by the oxide loading of the casting sol.

2b. Shaped Zirconia Articles, CC2

The shaped zirconia gels were dried to form aerogels using supercritical CO₂ extraction in the manner described in the Examples Section of U.S. Patent Application Publication US20180044245. The shaped zirconia aerogels were crack-free after drying.

These shaped zirconia aerogels were placed on a bed of zirconia beads in an alumina crucible. The crucible was covered with an alumina crucible and fired in air according to the following schedule:
a) Heat from 20° C. to 220° C. at 18° C./hour rate;
b) Heat from 220° C. to 244° C. at 1° C./hour rate;
c) Heat from 244° C. to 400° C. at 6° C./hour rate;
d) Heat from 400° C. to 1020° C. at 60° C./hour rate; and
e) Cool from 1020° C. to 20° C. at 120° C./hour rate.

The pre-sintered shaped zirconia articles were placed on a bed of zirconia beads in an alumina crucible. The crucible was covered with an alumina crucible and the samples were sintered in air according to the following schedule:
a) Heat from 25° C. to 1020° C. at 500° C./hour rate,
b) Heat from 1020° C. to 1200° C. at 120° C./hour rate,
c) Hold at 1200° C. for 2 hours,
d) Cool down from 1200° C. to 25° C. at 500° C./hour rate.

The resulting sintered zirconia articles (CC2) were crack-free and replicated the mold features precisely but reduced in size proportional to an amount of isotropic shrinkage determined by the oxide loading of the casting sol and with a visible grain structure when examined using SEM.

### SEM Imaging

The samples were embedded in epoxy and then cut with a diamond saw to make a rough cross-section. Then 80-100 micrometers (um) of material was removed at that cross-section to reveal a fresh smooth cross-section surface. The samples were mounted on an SEM stub, and a thin layer of Ir (approximately 2 nanometers (nm)) was deposited to make them conductive.
Imaging Conditions: 3.0 kV; 4 mm wd; Mode: LA-BSE
Magnification: 40 kx and 60 kx
Instrument: Hitachi 8230 Field Emission SEM (Hitachi, Tokyo, Japan)

The samples were examined using compositional electron imaging (LA-BSE), which uses backscattered electrons. LA-BSE is generally more affected by composition than the more typical Secondary Electron Imaging (SEI) which shows topography; areas of higher average atomic number appear brighter in BSE images. Crystallinity can also affect contrast in a compositional image.

### Physical Vapor Deposition (PVD) of Aluminum (Al)

The vapor coater used was a Denton Vacuum Optical Coater (Denton Vacuum LLC, Moorestown, NJ) comprising a 5-planet planetary drive system that is located ˜ 1 meter above a 4 pocket Temescal Electron Beam gun. The planetary is designed to hold the substrate (glass disk) perpendicular to the evaporation source and to move that disk in a planetary type motion in and out of the evaporation plume during the deposition. If the vapor coater is used in “standard” configuration, the entire surface of the substrate would be exposed to the aluminum evaporation plume. So, to eliminate this issue, a fixture was designed to hold the substrate at a 45-degree angle in reference to the electron beam gun (deposition angle α). In addition, the substrate was held stationary, so the bottom of the cavities were not in line-of-sight of the aluminum vapor plume. While this minimizes the bottom of the cavity from getting coated, it only coats one sidewall of the cavity. In order to coat the opposing sidewall of the cavity, the vapor coater was vented to atmosphere and the substrate was physically rotated on the fixture 180 degrees before running the vapor coater again.

The aluminum source material was prepared by cutting Al wire to about 1 inch (2.54 cm) long and “stacked” into a 10 mL FABMET crucible (Kurt J Lesker Company, Jefferson Hills, PA). The Al wire was then pre-melted to form a slug in the crucible using the Temescal Electron Beam Gun (Ferrotec Corp., Santa Clara, CA). The slug was used as the aluminum source during vapor deposition.

The process for coating Al was as follows:
a) Substrates were prepared for coating by adhering to the fixture using double sided tape at 45°, the deposition angle, α;
b) The vapor coater was vented to atmosphere and the planet was removed. At which point the fixture was installed on one planet and was moved to a stationary location directly above the electron beam source;
c) The chamber was closed and pumped to a vacuum level of <2×10⁻⁵ Torr;
d) When the vapor coater reached a low enough vacuum, the Temescal electron beam gun power supply was energized. A voltage of 10 kilovolts (kV) and a current of a few milliamps was applied to the e-gun's filament, heating the aluminum source material in the e-gun. The aluminum source was heated and controlled via an Inficon IC5 (Inficon, Bad Ragaz, Switzerland) deposition rate controller to the desired deposition rate of 15 angstroms/second to coat the sample. The deposition rate (i.e., thickness) was monitored with the Inficon Quartz Crystal Microbalance (QCM);
e) The power supply was turned off and the source was allowed to cool for about 10 minutes. The chamber is then vented back to atmospheric pressure;
f) In samples where more than one side wall of the cavity is coated, the coated substrate was physically rotated 180° and reattached to the fixture (remaining at 45 relative to the target), which was placed back above the electron beam gun within the coater to coat the other wall of the cavity with aluminum; and
g) The process was then restarted at step c), above, and the other wall was similarly coated.

### PVD of Polytetrafluoroethylene (PTFE)

The fluorinated coatings were deposited using a PVD 75 batch vapor coater from Kurt J. Lesker Co. Radio frequency (rf) sputtering in Argon gas was used to sputter fluorinated organic fragments from the PTFE target to the substrate. The substrate was mounted to a stationary bracket that supported the samples at different orientations, nominally parallel to the target surface is considered 0°. The table below shows the distances from the target and the orientations of the samples (deposition angle—normal is 90°). These orientations put the substrate at angles relative to the sputter source such that different degrees of shadowing into the cavities were achieved.

| | | Deposition Angle |
|---|---|---|
| Bracket | Distance from | α (normal to |
| Angle, | Target to Sample, | substrate surface |
| degrees | inch (cm) | is 90°), degrees |
| 0° (horizontal) | 4.60 (11.68) | 44° |
| 35° | 6.25 (15.88) | 57° |
| 55° | 6.10 (15.49) | 76° |
| 75° | 5.90 (14.99) | 79° |

The PTFE source material was a circular disc PTFE target supplied by QS Advanced Materials (Troy, MI), 3 inches (7.62 cm) in diameter and milled down to 0.063 inches (0.160 cm) thick, mounted on a copper plate.

The process for coating PTFE was as follows:
a) Silica disks were prepared for coating by adhering to the bracket using looped polyimide tape on the back of the disks;
b) The vapor coater was vented to atmosphere and the bracket was installed onto the platen to hold the samples stationary during deposition;
c) The chamber was closed and pumped to a vacuum level of ˜2.8×10⁻⁵ Torr;
d) When the vapor coater was at a low enough vacuum, the chamber was backfilled to 15 milliTorr (mTorr) with Ar. The rf plasma was ignited at this pressure and then the Ar pressure was reduced to 1 mTorr for the deposition and the rf power was set to 50 W;
e) The shutter over the PTFE target was opened to expose the samples to the flux of fluorinated material coming from the target for the desired time to realize the goal of 30 nm thickness; and
f) The power supply was turned off and the chamber was vented to enable removal of the coated samples.

### PVD of Gold (Au)

The gold coatings were deposited using a PVD 75 batch vapor coater from Kurt J. Lesker Co. Radio frequency (rf) sputtering in Argon gas was used to sputter gold atoms from the Au target to the nanostructured cast ceramic disks. The discs were mounted to a stationary bracket that supported the samples at different orientations. These orientations put the samples at angles relative to the sputter source (deposition angles) such that different degrees of shadowing into the nanowells were achieved.

The process for coating Au was similar to that of PTFE (above), except that the chamber was backfilled to 2 mTorr with Ar and the rf power was 200 W. The shutter was opened for the appropriate time to realize the desired coating thickness.

### PVD of Silver-Gold Alloy (AgAu)

The silver/gold alloy coatings were deposited using the same system and procedure as described above for PVD of Au, with the exception that a 50:50 Ag:Au alloy target was used.

### Comparative Example A

Comparative Example A was CCI without further treatment. The sintered article comprised a plurality of cylindrical cavities having an average a depth of 225 nm, and an average diameter of 135 nm as determined by SEM, giving an aspect ratio (diameter/height) of about 0.6.

### Comparative Example B

Comparative Example B was CC2 without further treatment. The sintered article comprised a plurality of cylindrical cavities having a calculated depth of about 194 nm, and an average diameter of 727 nm as determined by SEM, giving an aspect ratio (diameter/height) of about 3.7. A top view of this sample is shown in FIG. 7.

### Example 1

For Example 1, CC1 was used as the substrate, which was coated with aluminum following the PVD of Aluminum procedure described above up to step (e) with an a of 45 resulting in a coating thickness of 20 nm. After completion of step (e), the coated substrate was rotated 180 and then coated for a second time at 45°, again with a coating thickness of 20 nm. The average interstitial coating thickness along the upper surface was 40 nm.

### Example 2

For Example 2, CCI was used as the substrate, which was coated with aluminum following the PVD of Aluminum procedure described above with an a of 45°. The average coating thickness was 80 nm. The SEM images for this sample show a thicker coating on the top surface (interstitial) than in Example 1. This sample shows coating on the side wall, thickest near the top of the cavity and thinning with the depth of the sidewall. The coating appears to cover most of the sidewall and none of the bottom surface.

### Example 3

For Example 3, CCI was used as the substrate, which was coated with PTFE following the PVD of PTFE procedure described above with a deposition angle, α, of 44°.

### Comparative Example C

Comparative Example C was prepared similar to Example 3 with an a of 76°. SEM imaging of the sample appeared to show the PTFE deposited on the side walls and bottom of the cavities indicating no selective coating of the patterned substrate.

### Example 4

For Example 4, CCI was used as the substrate, which was coated with 37 nm of 50:50 wt % AgAu alloy at a 35 deposition angle α following PVD of AgAu alloy procedure described above.

### Example 5

For Example 5, CCI was used as the substrate, which was coated with 72 nm of a 50:50 wt % AgAu alloy at 35 deposition angle α according the procedure for PVD of AgAu Alloy described above.

### Sample 6

For Sample 6, a 2 cm×2 cm chip of a silicon wafer (PWPT15725 available from MEMC Korea Co.) was coated with 72 nm of 50:50 wt % AgAu alloy deposition at 35 angle α according the procedure for PVD of AgAu Alloy described above. The AgAu-coated substrate was immersed in a solution of 0.1 wt % HFPO Thiol in Novec 7100 for 1-2 minutes. Afterwards, the sample was rinsed with neat Novec 7100, followed by IPA, and dried with nitrogen gas. High resolution x-ray photoelectron spectroscopy confirmed the successful deposition of the HFPO Thiol onto the AgAu layer. Although the silicon wafer chip did not comprise any surface features (e.g., cavities), this experiment proved that HFPO Thiol could be used to successfully bind to the AgAu layer.

### Prophetic Example 7

For Prophetic Example 7, CCI is used as the substrate. CCI is coated with aluminum following the PVD of Aluminum procedure described above with a deposition angle of 45. The Al-coated substrate is immersed in solution of 0.1 wt % HFPO Phosphate Ester in Novec 7100 for 1-2 minutes. Afterwards, the sample is rinsed with neat Novec 7100, followed by IPA, and then dried with nitrogen gas.

Foreseeable modifications and alterations of this invention will be apparent to those skilled in the art without departing from the scope and spirit of this invention. This invention should not be restricted to the embodiments that are set forth in this application for illustrative purposes. To the extent that there is any conflict or discrepancy between this specification as written and the disclosure in any document mentioned or incorporated by reference herein, this specification as written will prevail.

1. A coated article comprising:
(a) A substrate comprising a ceramic, a glass, or a glass ceramic, wherein the substrate comprises a surface, the surface comprising a continuous upper portion and a plurality of lower portions, wherein each lower portion is connected to the upper portion by at least one sidewall; and
(b) A first layer comprising a material capable of physical vapor deposition, wherein the first layer is disposed on the continuous upper portion and at least a portion of each sidewall, and wherein at least a portion of each lower portion is free of the first layer.

2. The coated inorganic article of claim 1, wherein the material capable of physical vapor deposition comprises at least one of a polymer, an oligomer, or a small molecule, which is optionally fluorinated.

3. (canceled)

4. The coated article of claim 1, wherein the material capable of physical vapor deposition comprises at least one of: a metal, a metal alloy, a metal oxide, a metal nitride, a metal oxynitride, a metal fluoride, a metal sulfide, and a metal carbide.

5. The coated article of claim 4, wherein the material capable of physical vapor deposition comprises a metal, wherein the metal comprises at least one of: Al, Ti, Au, Ag, Cu, Ni, Si, V, Co, and Cr.

6. The coated article of claim 1, wherein the material capable of physical vapor deposition comprises at least one of aluminum, titanium, gold, gold-silver alloy, polytetrfluoroethylene, polyhexafluoropropylene, polyvinylidene fluoride, poly(2,2-bistrifluoromethyl-4,5-difluoro-1,3-dioxole), and combinations or blends thereof.

7. The coated article of claim 1, wherein the first layer disposed on the continuous upper portion has an average thickness of at least 1 nm and at most 500 nm.

8. The coated article of claim 1, wherein at least a portion of each lower portion of the surface is free of the first layer.

9. The coated article of claim 1, wherein the at least one side wall is substantially perpendicular to the continuous upper portion.

10. The coated article of claim 1, wherein the at least one sidewall is oblique to the continuous upper portion.

11. The coated article of claim 1, wherein a cavity defined by the at least one sidewall and the lower portion has a volume of at least 1 micrometer³ and at most 5 micrometer³.

12. The coated article of claim 1, wherein the substrate comprises silica or zirconia.

13. The coated article of claim 1, wherein the substrate is derived from (a) 2 to 65 weight percent surface modified silica particles based on a total weight of the casting sol, wherein the surface modified silica particles comprise a reaction product of silica particles having an average particle size no greater than 100 nanometers and a surface modification agent composition comprising a silane modification agent having a radically polymerizable group and wherein the surface modified silica particles are 50 to 99 weight percent silica and wherein the casting sol contains no more than 50 weight percent silica:
(b) 0 to 40 weight percent polymerizable material based on the total weight of the casting sol, wherein the polymerizable material does not contain a silyl group;
(c) 0.01 to 5 weight percent radical initiator based on the total weight of the casting sol: and
(d) 30 to 90 weight percent organic solvent medium based on the total weight of the casting sol, wherein the surface modification composition, the polymerizable material, and the radical initiator are soluble in the organic solvent medium.

14. The coated article of claim 1, wherein the substrate is derived from
(a) 20 to 60 weight percent zirconia-based particles based on a total weight of the reaction mixture, the zirconia-based particles having an average particle size no greater than 100 nanometers and containing at least 70 mole percent ZrO₂, (b) 30 to 75 weight percent of a solvent medium based on the total weight of the reaction mixture, the solvent medium containing at least 60 percent of an organic solvent having a boiling point equal to at least 150° C., (c) 2 to 30 weight percent polymerizable material based on a total weight of the reaction mixture, the polymerizable material including a first surface modification agent having a free radical polymerizable group; and (d) a photoinitiator for a free radical polymerization reaction.

15. The coated article of claim 1, further comprising a second layer disposed on the first layer, wherein the second layer is derived from compound comprising at least one of: a silane, a thiol, a phosphate, a phosphonic acid, a monophosphate ester, a sulfate, a sulfonic acid, a carboxylic acid, a hydroxamic acid, an amine containing heteroaromatic ring, and a nitrogen containing heteroaromatic ring.

16. The coated article of claim 15 where the second layer coating is biologically inert.

17. The coated article of claim 15 where the second layer comprises a fluorinated material, a polyalkyene oxide, a polyolefin, a silicone, or combinations thereof.

18. The coated article of claim 16, wherein the second layer coating comprises a biomolecule or a biologically active molecule.

19. A method of making an article, the method comprising:
(a) Obtaining a substrate comprising ceramic, glass, or combinations thereof, wherein the substrate comprises a surface, the surface comprising a continuous upper portion and a plurality of lower portions, wherein each lower portion is connected to the upper portion by at least one sidewall; and
(b) Depositing a material capable of physical vapor deposition from a source onto the surface of the substrate to form a first layer of a coated substrate, wherein the substrate is held to an angle versus the source such that the material is disposed on the continuous upper portion and at least a portion of each sidewall and wherein at least a portion of each lower portion is free of the material.

20. The method of claim 19, further comprising contacting the coated substrate with a second layer, where the second layer is substantially disposed on top of the first layer to form a protected article.

21. (canceled)

22. A coated article comprising:
(a) A substrate comprising a ceramic, a glass, or a glass ceramic, wherein the substrate comprises an upper surface and a plurality of cavities, wherein the plurality of cavities is open to the upper surface of the substrate, wherein the plurality of cavities has an average depth and an average cavity width;
(b) a reference line, wherein the reference line is at an angle from the upper surface of the substrate, wherein the angle is less than or equal to the arctangent of the average cavity depth divided by the average cavity width; and
(c) a first layer comprising a material capable of physical vapor deposition, wherein the first layer creates an unobstructed surface back to the reference line.
